(19) United States
(12) Patent Application Publication
(10) Pub. No.: US 2024/0074259 A1
(43) Pub. Date: Feb. 29, 2024

(54) DISPLAY DEVICE

(71) Applicant: Samsung Display Co., Ltd., Yongin-si (KR)

(72) Inventors: JONG-HWA KIM, Yongin-si (KR); IL-JOO KIM, Yongin-si (KR); CHANGHO LEE, Yongin-si (KR); HWAN-HEE JEONG, Yongin-si (KR); WONJUN CHOI, Yongin-si (KR)

(21) Appl. No.: 18/358,462

(22) Filed: Jul. 25, 2023

(30) Foreign Application Priority Data
Aug. 24, 2022 (KR) 10-2022-0106472

(51) Int. Cl. H10K 59/131

(52) U.S. Cl. CPC H10K 59/131

(57) ABSTRACT

A display device includes a base substrate including a first area, a second area, and a third area between the first and second areas and bendable to a degree, insulating layers on the base substrate, a signal line overlapping the first to third areas and including a first line portion in the first area, a second line portion in the first area, the second area, and the third area and on a layer different from the first line portion, and a first connection portion in the first area and on a layer different those of the first and second line portions, wherein the second line portion is connected to a second portion of the first connection portion via a single second contact hole defined in an insulating layer between the second line portion and the second portion of the first connection portion, the insulating layer being an organic layer.

### CROSS-REFERENCE TO RELATED APPLICATIONS

This application claims priority to and the benefit of Korean Patent Application No. 10-2022-0106472 filed on Aug. 24, 2022, in the Korean Intellectual Property Office, the disclosure of which is incorporated by reference herein in its entirety.

### BACKGROUND

### 1. Field

Embodiments of the present disclosure described herein relate to a display device.

### 2. Description of the Related Art

Electronic devices such as smart phones, tablet computers, laptop computers, vehicle navigation systems, smart televisions, and the like are being have become ubiquitous. Such electronic devices have a display device for providing information to a user.

Various types of display devices are being developed for providing satisfactory user experience (UX) and user interface (UI). Currently, an area of focus is the development of flexible display devices. In addition, display devices having a slim bezel are of particular interest.

The above information disclosed in this Background section is for enhancement of understanding of the background of the present disclosure, and therefore, it may contain information that does not constitute prior art.

### SUMMARY

Aspects of embodiments of the present disclosure are directed to a display device with reduced signal line defects.

According to some embodiments, there is provided a display device including: a base substrate including a first area, a second area spaced apart from the first area in a first direction, and a third area between the first area and the second area in the first direction and bendable to a set degree; a plurality of insulating layers on the base substrate; a pixel on the first area; and a signal line overlapping the first area, the second area, and the third area, wherein the signal line includes: a first line portion in the first area; a second line portion in the first area, the second area, and the third area and on a layer different from a layer of the first line portion; and a first connection portion in the first area and on a layer different from layers of the first line portion and the second line portion, wherein a first portion of the first connection portion is connected to the first line portion via at least one first contact hole defined in an insulating layer of the insulating layers between the first portion of the first connection portion and the first line portion, and wherein the second line portion is connected to a second portion of the first connection portion via a single second contact hole defined in an insulating layer of the insulating layers between the second line portion and the second portion of the first connection portion, the insulating layer being an organic layer.

In some embodiments, the signal line further includes: a third line portion in the second area; and a second connection portion in the second area and on a layer different from layers of the second line portion and the third line portion, wherein a first portion of the second connection portion is connected to the third line portion via at least one third contact hole defined in an insulating layer of the insulating layers between the first portion of the second connection portion and the third line portion, and wherein the second line portion is connected to a second portion of the second connection portion via a single fourth contact hole defined in an insulating layer of the insulating layers between the second line portion and the second portion of the second connection portion, the insulating layer being an organic layer.

In some embodiments, the second insulating layer and the fourth insulating layer are a same organic layer.

In some embodiments, the at least one first contact hole comprises a plurality of first contact holes, wherein the first insulating layer comprises a plurality of inorganic layers.

In some embodiments, the organic layer is on the plurality of inorganic layers.

In some embodiments, a contact area of the second contact hole is larger than a sum of contact areas of the plurality of first contact holes.

In some embodiments, a diameter of the second contact hole is equal to or greater than 10 micrometers.

In some embodiments, the second line portion includes: a connected portion overlapping the second portion of the first connection portion; and a plurality of line portions extending in the first direction from the connected portion, arranged in a second direction crossing the first direction, and overlapping the third area.

In some embodiments, the display device further includes: a scan driving circuit that is in the first area and provides a scan signal to the pixel, wherein the signal line is connected to the scan driving circuit.

In some embodiments, the signal line includes a first signal line configured to receive a first bias voltage and a second signal line configured to receive a second bias voltage lower than the first bias voltage.

In some embodiments, a voltage difference between the first bias voltage and the second bias voltage is equal to or greater than about 10 V.

In some embodiments, in the signal line is electrically connected to the pixel.

In some embodiments, the plurality of insulating layers include: a plurality of upper organic layers overlapping the first area and on the first line portion and the first connection portion; and at least one inorganic layer overlapping the first area, not overlapping the third area, and on the plurality of upper organic layers.

In some embodiments, a portion of an upper organic layer in contact with the first line portion among the plurality of upper organic layers is inside the second contact hole.

In some embodiments, the display device further includes: a capping electrode, wherein the plurality of insulating layers overlap the first area and the third area, and includes a first organic layer on the second line portion and a second organic layer on the first organic layer, wherein the first organic layer defines an opening overlapping the second contact hole and exposing a portion of the second line portion, and wherein the capping electrode is on the exposed portion of the second line portion.

In some embodiments, the second contact hole is inside the opening in a plan view.

In some embodiments, rein the first area of the first connection portion and the second area of the first connection portion are aligned in a second direction crossing the first direction.

According to some embodiments, there is provided a display device including: a base substrate including a first area, a second area spaced apart from the first area in a first direction, and a third area between the first area and the second area; a plurality of inorganic layers on the base substrate, and defining an opening extending in a second direction crossing the first direction and overlapping the third area; a plurality of organic layers on the plurality of inorganic layers; a pixel on the base substrate and overlapping the first area; and a signal line overlapping the first area, the second area, and the third area, wherein the signal line includes: a first line portion in the first area; a second line portion in the first area, the second area, and the third area and on a layer different from a layer of the first line portion; and a first connection portion in the first area and on a layer different from layers of the first line portion and the second line portion, wherein a first portion of the first connection portion is connected to the first line portion via a plurality of first contact holes defined in at least one inorganic layer of the inorganic layers between the first portion of the first connection portion and the first line portion, wherein the second line portion is connected to a second portion of the first connection portion via a second contact hole defined in at least one organic layer of the organic layers between the second line portion and the second portion of the first connection portion, wherein a diameter of the second contact hole is equal to or greater than about 10 micrometers.

In some embodiments, a portion of an organic layer on the at least one organic layer among the plurality of organic layers is inside the second contact hole.

In some embodiments, the display device further includes: a capping electrode, wherein an opening having a larger area than the second contact hole and exposing a portion of the second line portion is defined in a first upper organic layer on the at least one organic layer among the plurality of organic layers, wherein the capping electrode is inside the opening and covers the exposed portion of the second line portion, wherein a second upper organic layer on the first upper organic layer is inside the opening.

### BRIEF DESCRIPTION OF THE DRAWINGS

The above and other objects and features of the present disclosure will become apparent by describing in detail embodiments thereof with reference to the accompanying drawings.

FIGS. 1A and 1B are perspective views of a display device according to some embodiments of the present disclosure.

FIG. 2 is a cross-sectional view of a display device according to some embodiments of the present disclosure.

FIG. 3 is a plan view of a display panel according to some embodiments of the present disclosure.

FIG. 4 is a first cross-sectional view of a display device according to some embodiments of the present disclosure.

FIG. 5 is a second cross-sectional view of a display device according to some embodiments of the present disclosure.

FIG. 6A is a plan view of a signal line according to some embodiments of the present disclosure.

FIG. 6B is a first cross-sectional view of a signal line according to some embodiments of the present disclosure.

FIG. 6C is a second cross-sectional view of a signal line according to some embodiments of the present disclosure.

FIGS. 7A and 7B are plan views of a signal line according to some embodiments of the present disclosure.

FIG. 8A is a plan view of a signal line according to some embodiments of the present disclosure.

FIG. 8B is a first cross-sectional view of a signal line according to some embodiments of the present disclosure.

### DETAILED DESCRIPTION

The present invention may be implemented in various forms and have specific embodiments some of which are illustrated in the drawings and described in detail in the text below. It is to be understood, however, that the invention is not intended to be limited to the particular forms disclosed, but on the contrary, is intended to cover all modifications, equivalents, and alternatives falling within the spirit and scope of the invention.

Hereinafter, embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

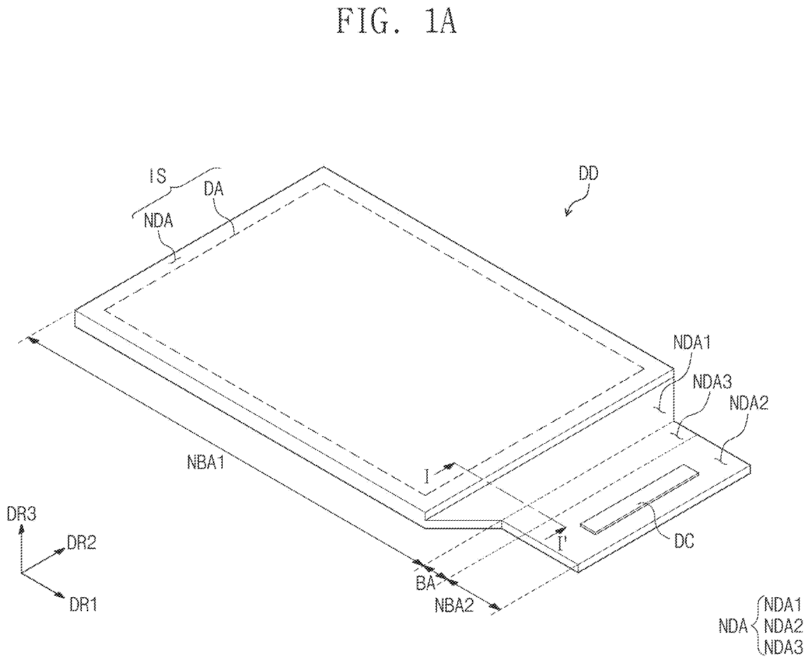

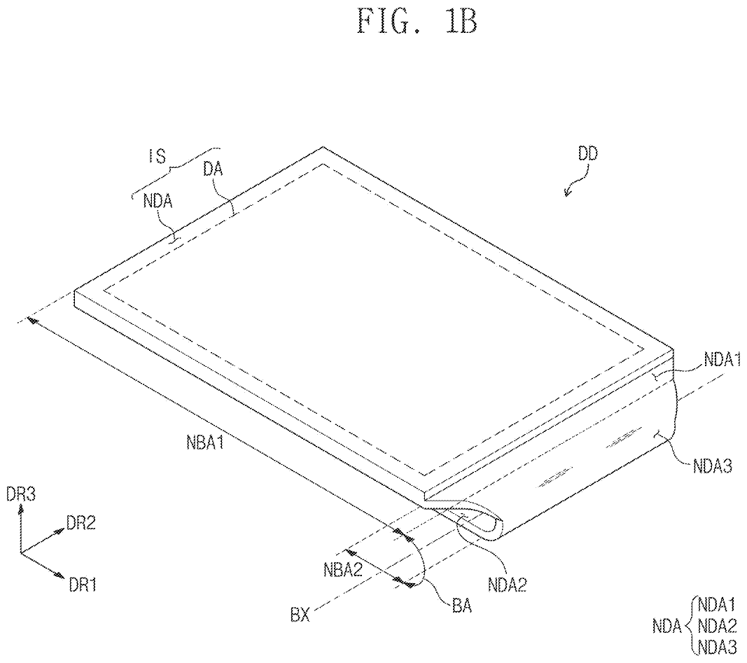

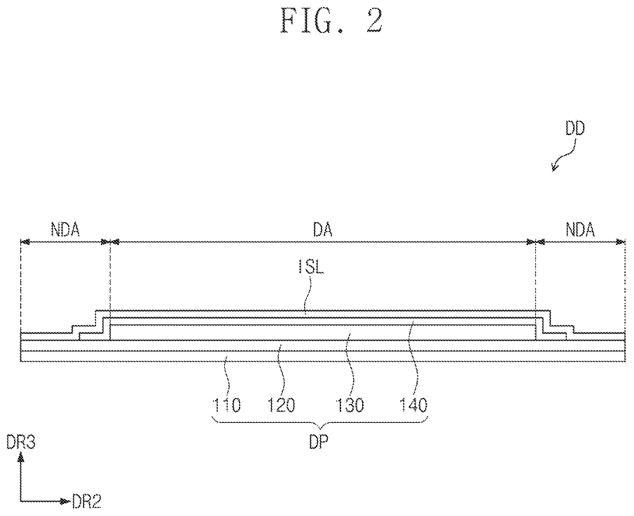

FIGS. 1A and 1B are perspective views of a display device DD according to some embodiments of the present disclosure. FIG. 2 is a cross-sectional view of the display device DD according to some embodiments of the present disclosure.

As shown in FIGS. 1A and 1B, a display surface IS on which an image is displayed is parallel to a plane defined by a first direction axis DR1 and a second direction axis DR2. A third direction axis DR3 indicates a normal direction of the display surface IS, that is, a thickness direction of the display device DD. Front surfaces (or top surfaces) and rear surfaces (or bottom surfaces) of members are distinguished from each other by the third direction axis DR3. Hereinafter, first to third directions are directions respectively indicated by the first to third direction axes DR1, DR2, and DR3 and refer to by the same reference numerals.

As shown in FIGS. 1A and 1B, the display device DD includes a display area DA on which the image is displayed and a non-display area NDA adjacent to (e.g., surrounding) the display area DA. The non-display area NDA is an area in which no image is displayed. The non-display area NDA may enclose the display area DA.

According to some embodiments, a partial area of the display device DD may be bent to a suitable degree to have a suitable curvature (e.g., predetermined curvature). The display device DD includes a first non-bendable area NBA1 (hereinafter, a first area), a second non-bendable area NBA2 (hereinafter, a second area) spaced apart from the first non-bendable area NBA1 in the first direction DR1 in an unbent state, and a bendable area BA (hereinafter, a third area) defined between the first non-bendable area NBA1 and the second non-bendable area NBA2. The first area NBA1 may include the display area DA and a partial area of the non-display area NDA (hereinafter, a first non-display area NDA1). The second area NBA2 may include another partial area (hereinafter, referred to as a second non-display area NDA2) of the non-display area NDA, and the third area BA may include an area (hereinafter, a third non-display area NDA3) between the first non-display area NDA1 and the second non-display area NDA2.

The third area BA may be bent along a bending axis BX defined as the second direction DR2. The third area BA and the second area NBA2 may have widths in the second direction DR2 that are smaller than the width of the first area NBA1. A driving chip DC may be mounted in the second area NBA2. In one example, the driving chip DC may be mounted on a circuit board without being limited thereto, and the circuit board may be electrically connected to the second area NBA2.

As the third area BA is bent, the second area NBA2 may be positioned to face the first area NBA1, so that an area of the non-display area NDA seen from the display surface IS (or seen from a plan view) may be reduced. When comparing the bent state of the display device DD in FIG. 1B to the display device DD shown in FIG. 1A, it may be seen that the area of the non-display area NDA is reduced by at least the second area NBA2 in the bent state. As such, an area of a bezel area of the display device DD may be reduced when the third area BA is bent.

The description pertaining to the first area NBA1, the second area NBA2, and the third area BA described above may also be applicable to each of a display panel DP and an input sensor ISL, which are components of the display device DD. The description pertaining to the display area DA and the non-display area NDA may also be equally applicable to the display panel DP. The input sensor ISL may include a sensing area corresponding to the display area DA and a non-sensing area corresponding to the non-display area NDA.

In some embodiments, the display area DA has a rectangular shape. However, embodiments of the present disclosure are not limited thereto, and the shape of the display area DA and a shape of the non-display area NDA may be changed as appropriate. For example, the non-display area NDA may be disposed adjacent to only a partial area of the display area DA. Although the display device DD that is utilized in a mobile phone is illustrated as an example, embodiments of the present disclosure are not limited thereto. The display device DD may be utilized in large electronic devices such as televisions and monitors, as well as small and medium-sized electronic devices such as tablet personal computers (PCs), vehicle navigation systems, game consoles, and smart watches.

FIG. 2 is a cross-sectional view of the display device DD according to some embodiments of the present disclosure. FIG. 2 illustrates a cross-section defined by the second direction axis DR2 and the third direction axis DR3 of the first area NBA1.

As shown in FIG. 2, the display device DD includes the display panel DP and the input sensor ISL. The display device DD according to some embodiments of the present disclosure further includes a protection member disposed on a bottom surface of the display panel DP, an anti-reflection member and/or a window member disposed on a top surface of the input sensor ISL.

The display panel DP may be a light emitting display panel; however, embodiments of the present disclosure is not limited thereto. For example, the display panel DP may be an organic light emitting display panel or an inorganic light emitting display panel. In the organic light emitting display panel, a light emitting layer includes an organic light emitting material. In the inorganic light emitting display panel, a light emitting layer may include a quantum dot, a quantum rod, or a micro LED. Hereinafter, the display panel DP will be described as the organic light emitting display panel.

The display panel DP includes a base layer 110, a circuit element layer 120, a display element layer 130, and a thin film encapsulation layer 140 disposed on the base layer 110. The input sensor ISL may be directly disposed on the thin film encapsulation layer 140. As used herein, the phrase “a component A is directly disposed on a component B” means that no adhesive layer or other layer is disposed between the component A and the component B.

The base layer 110 may include at least one plastic film. The base layer 110, as a flexible substrate, may include a plastic substrate, a glass substrate, a metal substrate, or an organic/inorganic composite substrate. The base layer 110 may include an inorganic layer disposed between two organic layers. The display area DA, the non-display area NDA, the first area NBA1, the second area NBA2, and the third area BA described with reference to FIGS. 1A and 1B may be equally defined in the base layer 110.

The circuit element layer 120 includes at least one insulating layer and a circuit element. The insulating layer includes at least one inorganic layer and at least one organic layer. The circuit element includes signal lines, a driving circuit of a pixel, and the like. A further detailed description thereof is provided below.

The display element layer 130 includes a display element. The display element layer 130 may further include an organic layer such as a pixel defining film.

The thin film encapsulation layer 140 includes a plurality of thin films. Some thin films may be disposed to improve an optical efficiency, and some thin films may be disposed to protect organic light emitting diodes within the display element layer 130. A further detailed description of the thin film encapsulation layer 140 is provided below.

The input sensor ISL acquires coordinate information of an external input. The input sensor ISL may have a multi-layer structure. The input sensor ISL may include a single conductive layer or multiple conductive layers. The input sensor ISL may include a single insulating layer or multiple insulating layers. The input sensor ISL may sense the external input in a capacitive manner, for example. However, the operational scheme of the input sensor ISL is not limited thereto. For example, the input sensor ISL may sense the external input via an electromagnetic induction scheme or a pressure sensing scheme.

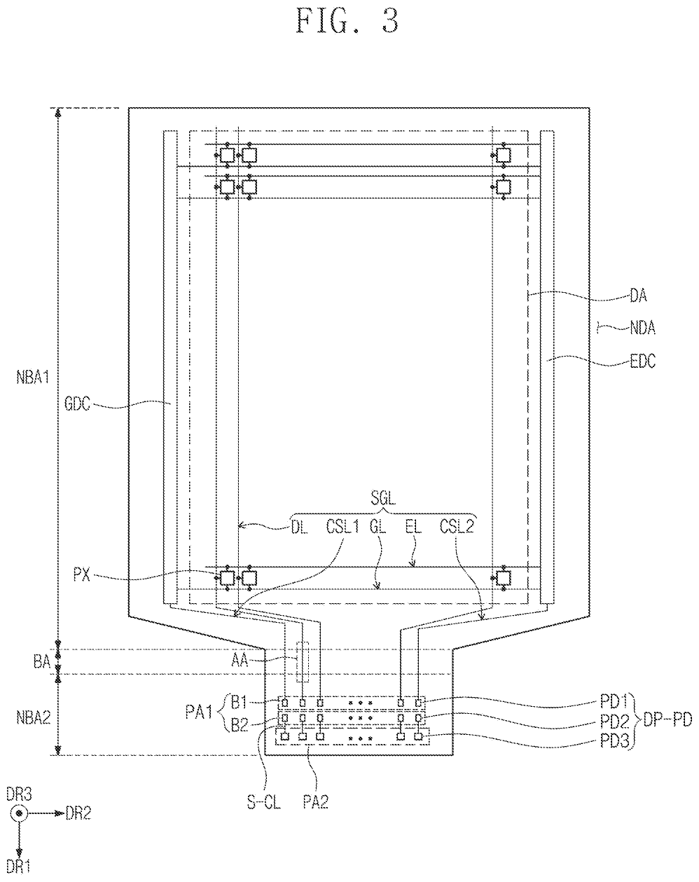

FIG. 3 is a plan view of the display panel DP according to some embodiments of the present disclosure.

As shown in FIG. 3, the display panel DP includes the display area DA and the non-display area NDA in the plan view. The display panel DP may include the first area NBA1, the second area NBA2, and the third area BA.

The display panel DP may include driving circuits GDC and EDC, a plurality of signal lines SGL, and a plurality of pixels PX. The plurality of pixels PX are disposed in the display area DA. Each of the pixels PX includes a light emitting element and a pixel driving circuit connected thereto. The driving circuits GDC and EDC, the plurality of signal lines SGL, and the pixel driving circuit may be included in the circuit element layer 120 illustrated in FIG. 2.

The driving circuits GDC and EDC may include the scan driving circuit GDC and the light emission driving circuit EDC disposed in the non-display area NDA. The scan driving circuit GDC generates a plurality of scan signals and sequentially outputs the plurality of scan signals to a plurality of scan lines GL to be described below. The light emission driving circuit EDC generates a plurality of pulse signals and sequentially outputs the plurality of pulse signals to a plurality of light emission signal lines EL that are described below. The light emission driving circuit EDC may correspond to a second scan driving circuit that generates a different type of scan signal activated in a section different from that of the scan driving circuit GDC.

Each of the scan driving circuit GDC and the light emission driving circuit EDC may include a plurality of thin film transistors formed via the same process as that of the driving circuit of the pixels PX, such as a low temperature polycrystaline silicon (LTPS) process or a low temperature polycrystalline oxide (LTPO) process.

The plurality of signal lines SGL includes the scan lines GL, the light emission signal lines EL, data lines DL, and signal transfer lines CSL1 and CSL2. Each of the data lines DL is connected to the corresponding pixel PX among the plurality of pixels PX. Each of the data lines DL provides a data signal from the driving chip DC (see, e.g., FIG. 1A) to the corresponding pixel PX among the plurality of pixels PX. The data lines DL overlap the first area NBA1, the second area NBA2, and the third area BA.

The signal transfer lines CSL1 and CSL2 may include the first signal transfer line CLS1, which provide signals to the scan driving circuit GDC, and the second signal transfer line CLS2, which provide signals to the light emission driving circuit EDC. The first signal transfer line CLS1 and the second signal transfer line CLS2 overlap the first area NBA1, the second area NBA2, and the third area BA.

Although each of the first signal transfer line CLS1 and the second signal transfer line CLS2 is illustrated as one signal line, it may include a plurality of signal lines. The first signal transfer line CLS1 and the second signal transfer line CLS2 may include a first signal line for receiving a first bias voltage and a second signal line for receiving a second bias voltage lower than the first bias voltage. A voltage difference between the first bias voltage and the second bias voltage may be equal to or greater than about 10 V, and may be in a range from about 20 V to about 30 V.

The first signal transfer line CLS1 and the second signal transfer line CLS2 may further include a third signal line for transferring a clock signal. The first signal transfer line CLS1 and the second signal transfer line CLS2 may include a plurality of third signal lines providing different clock signals.

Each of the scan driving circuit GDC and the light emission driving circuit EDC may receive the clock signal, the first bias voltage, and the second bias voltage so as to generate the pulse signal. The scan driving circuit GDC and the light emission driving circuit EDC may receive different clock signals. Levels of the first bias voltages received by the scan driving circuit GDC and the light emission driving circuit EDC may be different from each other, and levels of the second bias voltages received by the scan driving circuit GDC and the light emission driving circuit EDC may be different from each other.

The display panel DP may include a plurality of signal pads DP-PD disposed in the second area NBA2. The plurality of signal pads DP-PD may include first pads PD1, second pads PD2, and third pads PD3.

An area in which the first pads PD1 and the second pads PD2 are disposed may be defined as a first pad area PA1, and an area in which the third pads PD3 is disposed may be defined as a second pad area PA2. The first pad area PA1 may be an area that is bonded to the driving chip DC (see FIG. 1B), and the second pad area PA2 may be an area that is bonded to the circuit board (not shown). The first pad area PA1 may include a first area B1 in which the first pads PD1 are disposed and a second area B2 in which the second pads PD2 are disposed.

The first pad area PA1 and the second pad area PA2 may be spaced apart from each other in the first direction DR1. The second pads PD2 are connected to corresponding signal lines among the plurality of signal lines DL, CSL1, and CSL2. The second pads PD2 and the third pads PD3 may be connected to each other via connecting signal lines S-CL. Although one pad row is exemplarily illustrated in the first area B1, embodiments of the present disclosure are not limited thereto, and more pad rows may be present. The third pads PD3 may be bonded to pads of the circuit board.

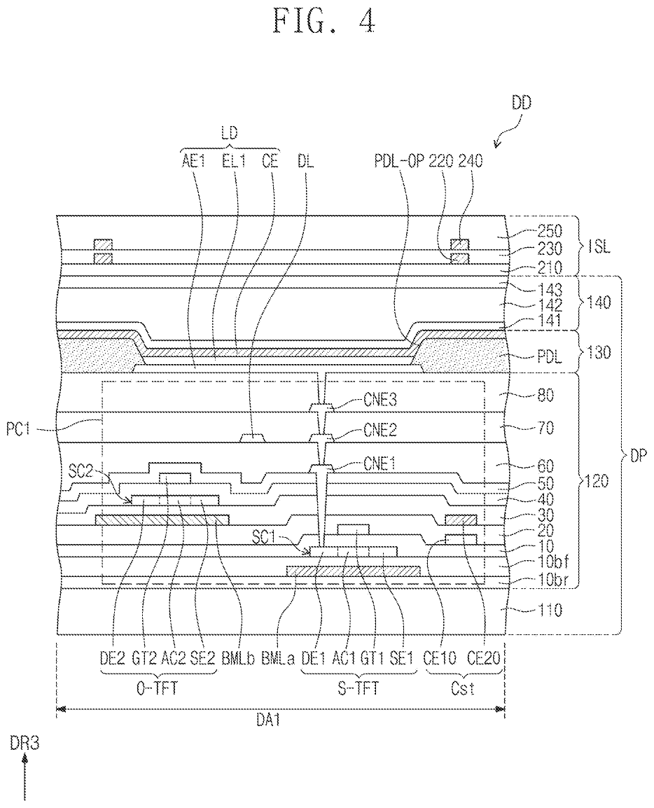

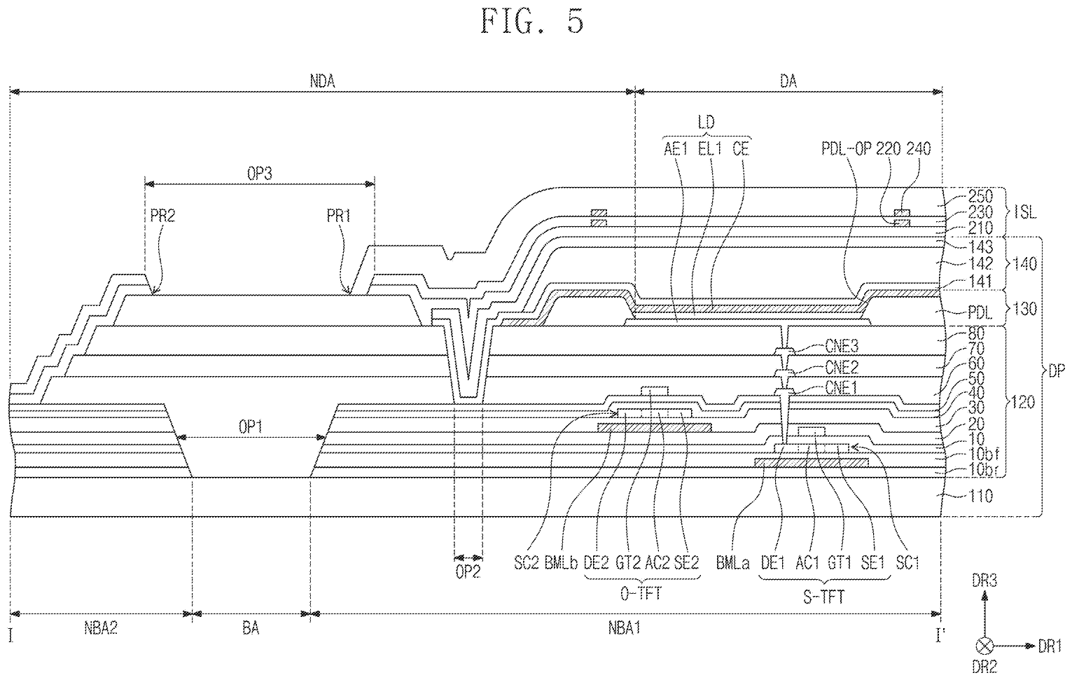

FIG. 4 is a first cross-sectional view of the display device DD according to some embodiments of the present disclosure. FIG. 5 is a second cross-sectional view of the display device DD according to some embodiments of the present disclosure. FIG. 4 shows a cross-section corresponding to the pixel PX in FIG. 3, and FIG. 5 shows a cross-section corresponding to the line I-I′ in FIG. 1A, centering on the insulating layer. FIGS. 4 and 5 show the insulating layers having thicknesses different from actual thicknesses thereof to illustrate the insulating layers more clearly. For example, the inorganic layers may have a thickness of about 10% to about 20% of a thickness of the organic layer.

FIG. 4 shows a portion of a light emitting element LD and a portion of a pixel circuit PC1. A silicon transistor S-TFT and an oxide transistor O-TFT are illustrated, as an example, as representative of the first pixel circuit PC1. The pixel circuit PC1 including both the silicon transistor S-TFT and the oxide transistor O-TFT will be described as an example, but the pixel circuit PC1 may include only the plurality of silicon transistors S-TFT or may include only the plurality of oxide transistors O-TFT.

Referring to FIG. 4, a barrier layer 10br may be disposed on the base layer 110. The barrier layer 10br prevents or substantially prevents foreign substances from entering from the outside. The barrier layer 10br may include at least one inorganic layer. The barrier layer 10br may include a silicon oxide layer and a silicon nitride layer. There may be a plurality of silicon oxide layers and a plurality of silicon nitride layers, and the silicon oxide layers and the silicon nitride layers may be alternately stacked on one another.

A first shielding electrode BMLa may be disposed on the barrier layer 10br. The first shielding electrode BMLa may include a metal. For example, the first shielding electrode BMLa may include molybdenum (Mo) with high (e.g., excellent) heat resistance, an alloy including the molybdenum, titanium (Ti), an alloy including the titanium, or the like. The first shielding electrode BMLa may receive a bias voltage. For example. the first shielding electrode BMLa may receive a power supply voltage. The first shielding electrode BMLa may block an electrical potential caused by polarization from affecting the silicon transistor S-TFT. The first shielding electrode BMLa may block external light from reaching the silicon transistor S-TFT. In some embodiments of the present disclosure, the first shielding electrode BMLa is a floating electrode isolated from another electrode or wiring.

A buffer layer 10bf may be disposed on the barrier layer 10br. The buffer layer 10bf may prevent diffusion of metal atoms or impurities from the base layer 110 to a first semiconductor pattern SC1 above. The buffer layer 10bf may include at least one inorganic layer. The buffer layer 10bf may include a silicon oxide layer and a silicon nitride layer.

The first semiconductor pattern SC1 may be disposed on the buffer layer 10bf. The first semiconductor pattern SC1 may include a silicon semiconductor. For example, the silicon semiconductor may include amorphous silicon, polycrystalline silicon, or the like. For example, the first semiconductor pattern SC1 may include low-temperature polysilicon.

FIG. 4 only shows a portion of the first semiconductor pattern SC1, and the first semiconductor pattern SC1 may be further disposed in another area. The first semiconductor pattern SC1 may be arranged in a specific rule across the pixel. The first semiconductor pattern SC1 may have portions having different electrical properties depending on whether the portions are doped or not. The first semiconductor pattern SC1 may include a first area having high conductivity (e.g., high electrical conductivity) and a second area having low conductivity (e.g., low electrical conductivity). The first area may be doped with an N-type dopant or a P-type dopant. A P-type transistor may include a doped area doped with the P-type dopant, and an N-type transistor may include a doped area doped with the N-type dopant. The second area may be a non-doped area or may be an area doped with a lower concentration than the first area.

The conductivity of the first area may be greater than that of the second area, and thus the first area may serve as or substantially serve as an electrode or a signal line. The second area may substantially correspond to a channel area (or an active area) of the transistor. In other words, a portion of the first semiconductor pattern SC1 may be a channel of the transistor, another portion thereof may be a source or a drain of the transistor, and still another portion thereof may be a connecting electrode or a connecting signal line.

A source area SE1, a channel area (e.g., an active area) AC1, and a drain area DE1 of the silicon transistor S-TFT may be formed from the first semiconductor pattern SC1. The source area SE1 and the drain area DE1 may extend in opposite directions from the channel area AC1 on a cross-section.

A first insulating layer 10 may be disposed on the buffer layer 10bf. The first insulating layer 10 may cover (e.g., may be on and overlap in a plan view) the first semiconductor pattern SC1. The first insulating layer 10 may be an inorganic layer. The first insulating layer 10 may be a single silicon oxide layer. The first insulating layer may have a multi-layer structure or a single-layer structure. The inorganic layer of the circuit element layer 120 to be described below may have a single-layer structure or a multi-layer structure, and may include at least one of the above-described materials; however, embodiments of the present disclosure are not limited thereto.

A gate GT1 of the silicon transistor S-TFT is disposed on the first insulating layer 10. The gate GT1 may be a portion of a metal pattern. The gate GT1 overlaps the channel area AC1. In a process of doping the first semiconductor pattern SC1, the gate GT1 may be a mask. A first electrode CE10 of a storage capacitor Cst is disposed on the first insulating layer 10. The first electrode CE10 may have a shape integral with the gate GT1 on the plan view.

A second insulating layer 20 may be disposed on the first insulating layer 10, and may cover the gate GT1. An upper electrode overlapping the gate GT1 may be disposed on the second insulating layer 20. A second electrode CE20 overlapping the first electrode CE10 may be disposed on the second insulating layer 20.

A second shielding electrode BMLb is disposed on the second insulating layer 20. The second shielding electrode BMLb may be disposed below the oxide transistor O-TFT to correspond thereto. In some examples of the present disclosure, the second shielding electrode BMLb may be omitted. For example, the first shielding electrode BMLa may be extended to a portion located below the oxide transistor O-TFT to replace the second shielding electrode BMLb.

A third insulating layer 30 may be disposed on the second insulating layer 20. A second semiconductor pattern SC2 may be disposed on the third insulating layer 30. The second semiconductor pattern SC2 may include a channel area AC2 of the oxide transistor O-TFT. The second semiconductor pattern SC2 may include an oxide semiconductor. For example, the second semiconductor pattern SC2 may include a transparent conductive oxide (TCO) such as an indium tin oxide (ITO), an indium zinc oxide (IZO), an indium gallium zinc oxide (IGZO), a zinc oxide (ZnOₓ), an indium oxide (In₂O₃), and/or the like.

The oxide semiconductor may include a plurality of areas distinguished from each other based on whether the transparent conductive oxide is reduced or not. An area in which the transparent conductive oxide is reduced (hereinafter, a reduced area) has greater conductivity than an area in which the transparent conductive oxide is not reduced (hereinafter, a non-reduced area). The reduced area substantially serves as the source/drain of the transistor or the signal line. The non-reduced area substantially corresponds to a semiconductor area (or the channel) of the transistor. In other words, a partial area of the second semiconductor pattern SC2 may be the semiconductor area of the transistor, another portion thereof may be the source area/drain area of the transistor, and still another portion thereof may be a signal transmitting area.

A fourth insulating layer 40 may be disposed on the third insulating layer 30. As shown in FIG. 4, the fourth insulating layer 40 may cover the oxide transistor O-TFT. In some embodiments of the present disclosure, the fourth insulating layer 40 is an insulating pattern that overlaps a gate GT2 of the oxide transistor O-TFT, and exposes a source area SE2 and a drain area DE2 of the oxide transistor O-TFT.

The gate GT2 of the oxide transistor O-TFT is disposed on the fourth insulating layer 40. The gate GT2 of the oxide transistor O-TFT may be a portion of the metal pattern. The gate GT2 of the oxide transistor O-TFT overlaps the channel area AC2.

A fifth insulating layer 50 may be disposed on the fourth insulating layer 40, and the fifth insulating layer 50 may cover the gate GT2. Each of the first insulating layer 10 to the fifth insulating layer 50 may be the inorganic layer.

A first connecting electrode CNE1 may be disposed on the fifth insulating layer 50. The first connecting electrode CNE1 may be connected to (e.g., physically and/or electrically connected to) the drain area DE1 of the silicon transistor S-TFT through a contact hole (e.g., an opening or contact opening) extending through the first to fifth insulating layers 10, 20, 30, 40, and 50.

A sixth insulating layer 60 may be disposed on the fifth insulating layer 50. A second connecting electrode CNE2 may be disposed on the sixth insulating layer 60. The second connecting electrode CNE2 may be connected to (e.g., physically and/or electrically connected to) the first connecting electrode CNE1 through a contact hole (e.g., an opening or contact opening) extending through the sixth insulating layer 60. The data line DL may be disposed on the sixth insulating layer 60. A seventh insulating layer 70 may be disposed on the sixth insulating layer 60, and may cover the second connecting electrode CNE2 and the data line DL. A third connecting electrode CNE3 may be disposed on the seventh insulating layer 70. The third connecting electrode CNE3 may be connected to the second connecting electrode CNE2 through a contact hole (e.g., an opening or contact opening) extending through the seventh insulating layer 70. An eighth insulating layer 80 may be disposed on the seventh insulating layer 70, and may cover the third connecting electrode CNE3. Each of the sixth insulating layer 60 to the eighth insulating layer 80 may be the organic layer.

In FIG. 5, the circuit element layer 120 including seven conductive layers, which includes the first shielding electrode BMLa, the gate GT1 of the silicon transistor S-TFT, the second shielding electrode BMLb, the gate GT2 of the oxide transistor O-TFT, the first connecting electrode CNE1, the second connecting electrode CNE2, and the third connecting electrode CNE3 is illustrated as an example. When the first to seventh conductive layers are patterned, the first shielding electrode BMLa, the gate GT1 of the silicon transistor S-TFT, the second shielding electrode BMLb, the gate GT2 of the oxide transistor O-TFT, the first connecting electrode CNE1, the second connecting electrode CNE2, and the third connecting electrode CNE3 are formed from the corresponding conductive layers. However, the number of conductive layers may be changed. For example, the circuit element layer 120 may include 4 to 7 conductive layers.

The light emitting element LD may include an anode (or a first electrode) AE1, a light emitting layer EL1, and a cathode (or a second electrode) CE. The cathode CE may be provided in common to the light emitting elements of the plurality of pixels PX (see, e.g., FIG. 3).

The anode AE1 of the light emitting element LD may be disposed on the eighth insulating layer 80. The anode AE1 may be a transmissive electrode, a semi-transmissive electrode, or a reflective electrode. A pixel defining film PDL may be disposed on the eighth insulating layer 80. The pixel defining film PDL may have a property of absorbing light, and, for example, the pixel defining film PDL may have a black color. The pixel defining film PDL may include a black coloring agent. The black coloring agent may include a black dye and/or a black pigment. The black coloring agent may include a metal such as carbon black and chromium, or an oxide thereof. The pixel defining film PDL may correspond to a light blocking pattern having a light blocking property.

The pixel defining film PDL may cover a portion of the anode AE1, and an opening PDL-OP exposing a portion of the anode AE1 may be defined in the pixel defining film PDL.

In some examples, a hole control layer may be disposed between the anode AE1 and the light emitting layer EL1. The hole control layer may include a hole transport layer and may further include a hole injection layer. An electron control layer may be disposed between the light emitting layer EL1 and the cathode CE. The electron control layer may include an electron transport layer and may further include an electron injection layer. The hole control layer and the electron control layer may be formed in common in the plurality of pixels PX (see, e.g., FIG. 3) using an open mask.

The thin film encapsulation layer 140 may be disposed on the display element layer 130. The thin film encapsulation layer 140 may include an inorganic layer 141, an organic layer 142, and an inorganic layer 143 sequentially stacked, but the layers constituting the thin film encapsulation layer 140 might not be limited thereto.

The inorganic layers 141 and 143 may protect the display element layer 130 from moisture and oxygen, and the organic layer 142 may protect the display element layer 130 from the foreign substances such as dust particles. The inorganic layers 141 and 143 may include a silicon nitride layer, a silicon oxynitride layer, a silicon oxide layer, a titanium oxide layer, an aluminum oxide layer, and/or the like. The organic layer 142 may include an acrylic organic layer; however, embodiments of the present disclosure are not limited thereto.

The input sensor ISL may be disposed on the display panel DP. The input sensor ISL may include at least one conductive layer and at least one insulating layer. In some embodiments, the input sensor ISL includes a first insulating layer 210, a first conductive layer 220, a second insulating layer 230, a second conductive layer 240, and a third insulating layer 250.

The first insulating layer 210 may be directly disposed on the display panel DP. The first insulating layer 210 may include an inorganic layer including at least one of a silicon nitride, a silicon oxynitride, and a silicon oxide. Each of the first conductive layer 220 and the second conductive layer 240 may have a single-layer structure or a multi-layer structure of layers stacked along the third direction DR3. Each of the first conductive layer 220 and the second conductive layer 240 may include conductive lines defining a mesh-shaped electrode. The conductive line of the first conductive layer 220 and the conductive line of the second conductive layer 240 may or might not be connected to each other via a contact hole (e.g., an opening) extending through the second insulating layer 230. A connection relationship between the conductive line of the first conductive layer 220 and the conductive line of the second conductive layer 240 may be determined based on a type of sensor formed by the input sensor ISL.

The first conductive layer 220 and the second conductive layer 240 having the single-layer structure may include a metal layer or a transparent conductive layer. The metal layer may include molybdenum, silver, titanium, copper, aluminum, or an alloy thereof. The transparent conductive layer may include the transparent conductive oxide such as the indium tin oxide (ITO), the indium zinc oxide (IZO), the zinc oxide (ZnOₓ), and/or an indium zinc tin oxide (IZTO). In addition, the transparent conductive layer may include a conductive polymer such as PEDOT, a metal nanowire, a graphene, and the like.

The first conductive layer 220 and the second conductive layer 240 having the multi-layer structure may include metal layers. The metal layers may have, for example, a three-layer structure of titanium/aluminum/titanium. A conductive layer of the multi-layer structure may include at least one metal layer and at least one transparent conductive layer.

The second insulating layer 230 covers the first conductive layer 220. The second insulating layer 230 may include an inorganic layer including at least one of the silicon nitride, the silicon oxynitride, and the silicon oxide. The third insulating layer 250 covers the second conductive layer 240. The third insulating layer 250 may include an organic layer.

Referring to FIG. 5, the inorganic layers 10br, 10bf, and 10 to 50 are disposed on the base layer 110. The inorganic layers 10br, 10bf, and 10 to 50 may include the barrier layer 10br, the buffer layer 10bf, and the first insulating layer 10 to the fifth insulating layer 50. The inorganic layers 10br, 10bf, and 10 to 50 overlap the first area NBA1 and the second area NBA2. In the inorganic layers 10br, 10bf, and 10 to 50, an opening (hereinafter, a first opening) OP1 corresponding to the third area BA may be defined. As shown in FIG. 1B, the first opening OP1 is defined (e.g., is created) to prevent the inorganic layers 10br, 10bf, and 10 to 50 from being damaged (or reduce damage thereto) by stress when the third area BA is bent. The first opening OP1 extends in the second direction DR2.

The organic layers 60, 70, 80, and PDL are disposed on the inorganic layers 10br, 10bf, and 10 to 50. The organic layers 60, 70, 80, and PDL may include the sixth insulating layer 60 to the eighth insulating layer 80 and the pixel defining film PDL. The sixth insulating layer 60 fills the first opening OP1.

In the sixth insulating layer 60 to the eighth insulating layer 80, an opening (hereinafter, a second opening) OP2 in the non-display area NDA of the first area NBA1 may be defined. The second opening OP2 may extend in the second direction DR2 and expose the fifth insulating layer 50. The inorganic layers 141 and 143 of the thin film encapsulation layer 140 may be disposed inside the second opening OP2 to be in contact with the fifth insulating layer 50.

The first insulating layer 210 and the second insulating layer 230 of the input sensor ISL, which are the inorganic layers, overlap (e.g., in a plan view) the first area NBA1 and the second area NBA2. In the first insulating layer 210 and the second insulating layer 230 of the input sensor ISL, an opening (hereinafter, a third opening) OP3 corresponding to the third area BA may be defined. As shown in FIG. 1B, the third opening OP3 is defined to prevent the first insulating layer 210 and the second insulating layer 230 of the input sensor ISL from being damaged (or to reduce damage thereto) by the stress when the third area BA is bent. The third opening OP3 extends in the second direction DR2. In some embodiments, the third insulating layer 250 of the input sensor ISL, which is the organic layer, overlaps the first area NBA1 and does not overlap the second area NBA2 and the third area BA; however, embodiments of the present disclosure are not limited thereto.

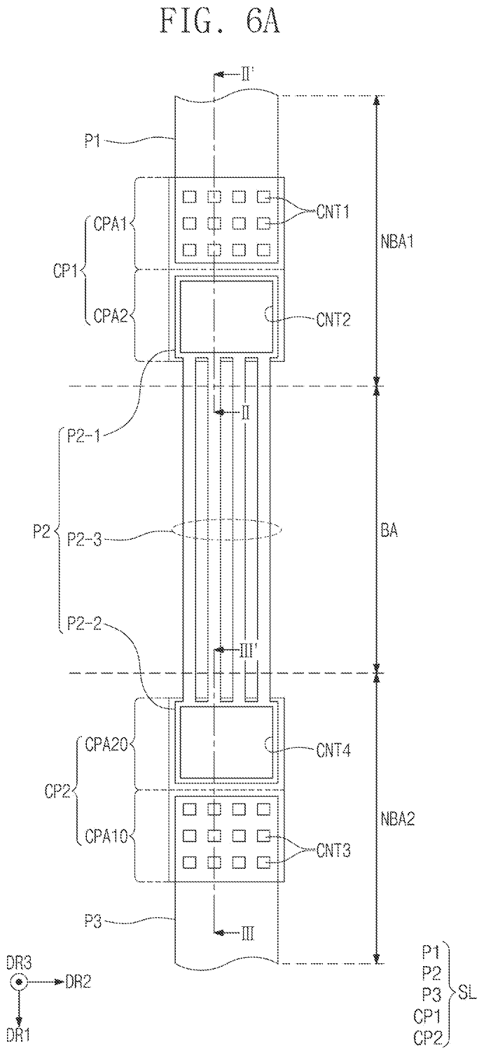

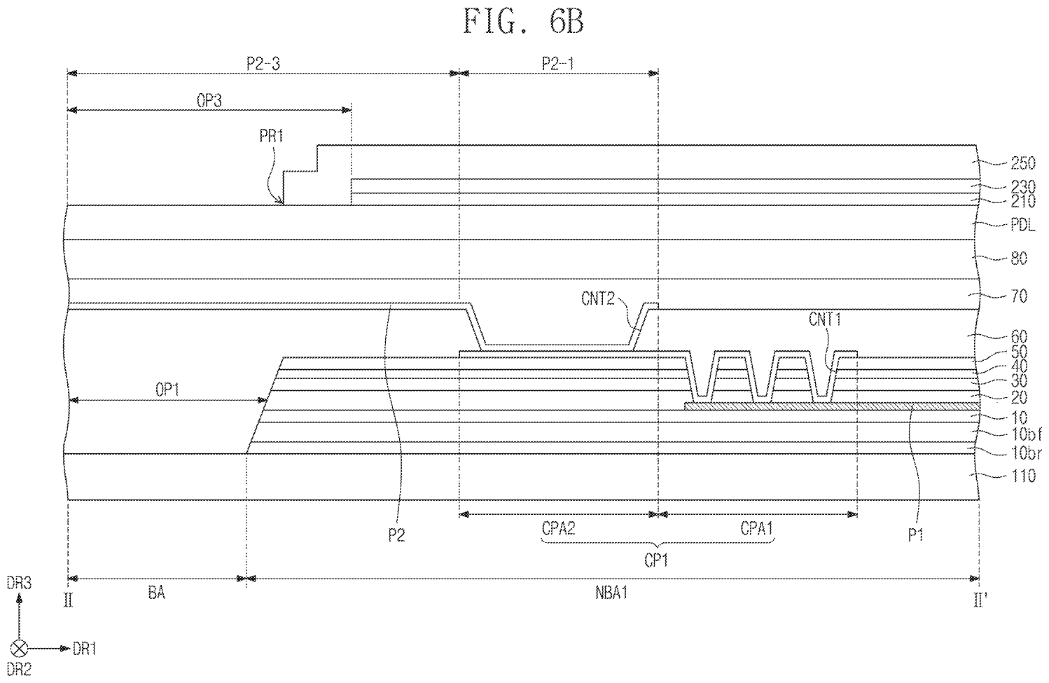

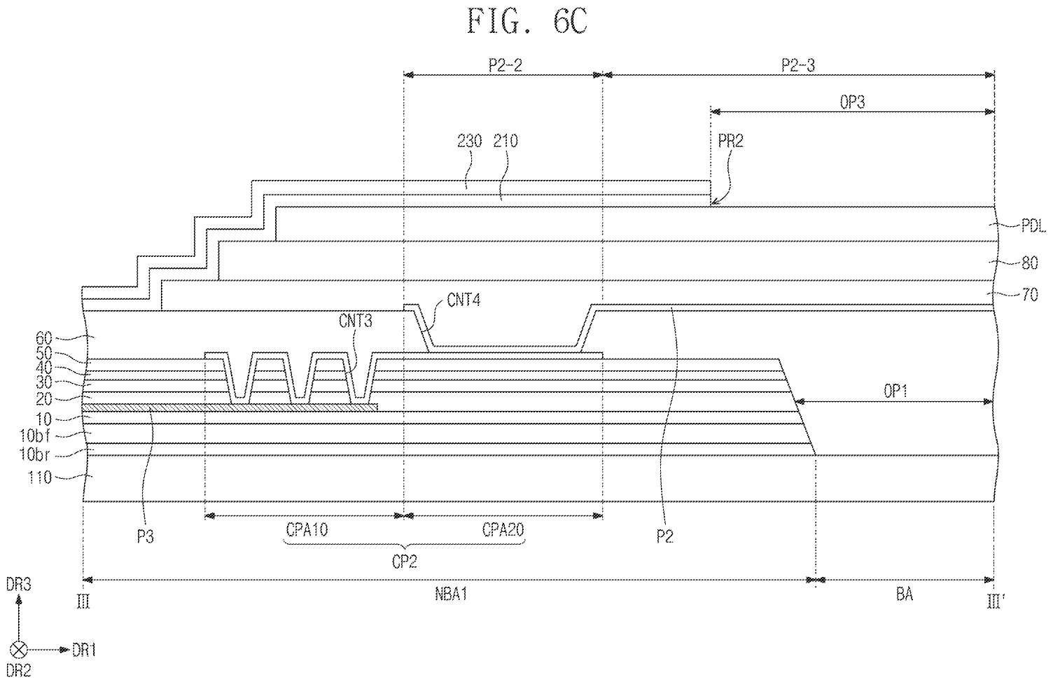

FIG. 6A is a plan view of a signal line SL according to some embodiments of the present disclosure. FIG. 6B is a first cross-sectional view of the signal line SL according to some embodiments of the present disclosure. FIG. 6C is a second cross-sectional view of the signal line SL according to some embodiments of the present disclosure.

The signal line SL shown in FIGS. 6A to 6C may correspond to the data lines DL or the signal transfer lines CLS1 and CLS2 described with reference to FIG. 3. For example, FIG. 6A may be an enlarged plan view of the data line DL disposed in the area AA shown in FIG. 3. However, the signal line SL is not limited by a type of signal or voltage to be transmitted but satisfies structural features to be described below.

The signal line SL may include a first line portion P1 disposed in the first area NBA1; a second line portion P2 disposed in the first area NBA1, the second area NBA2, and the third area BA; and a first connection portion CP1 disposed in the first area NBA1 and connecting the first line portion P1 and the second line portion P2 to each other. The first line portion P1, the second line portion P2, and the first connection portion CP1 may be disposed on different layers.

The first connection portion CP1 may include a first portion CPA1 overlapping the first line portion P1 and a second portion CPA2 overlapping the second line portion P2. In some embodiments, the first connection portion CP1 has a shape extending in the first direction DR1, and the first portion CPA1 and the second portion CPA2 are defined as different portions of the first connection portion CP1 in the first direction DR1.

According to the present embodiment, the signal line SL may further include a third line portion P3 disposed in the second area NBA2, and a second connection portion CP2 disposed in the second area NBA2 and connecting (e.g., electrically connecting) the second line portion P2 and the third line portion P3 to each other.

The second connection portion CP2 may include a first portion CPA10 overlapping the third line portion P3 and a second portion CPA20 overlapping the second line portion P2. In the present embodiment, the second connection portion CP2 has a shape extending in the first direction DR1, and the first portion CPA10 and the second portion CPA20 are defined as different portions of the second connection portion CP2 in the first direction DR1.

The second line portion P2 may include a first connected portion P2-1 overlapping the second portion CPA2 of the first connection portion CP1, a second connected portion P2-2 overlapping the second portion CPA20 of the second connection portion CP2, and a plurality of line portions P2-3 extending from the first connected portion P2-1 to the second connected portion P2-2. Each of the plurality of line portions P2-3 extends from the first connected portion P2-1 along the first direction DR1. The plurality of line portions P2-3 at least overlaps the third area BA. In FIG. 6A, the plurality of line portions P2-3 overlapping the first area NBA1, the second area NBA2, and the third area BA i shown as an example. In the third area BA, the plurality of line portions P2-3 is arranged in the second direction DR2 crossing (e.g., intersecting) the first direction DR1. The plurality of line portions P2-3 is arranged to lower a resistance of the second line portion P2 and improve flexibility thereof.

In some examples, the third line portion P3 and the second connection portion CP2 may be omitted. In this regard, the second connected portion P2-2 may extend to the first pad PD1 in FIG. 3. In other words, the first pad PD1 in FIG. 3 may be connected to the second connected portion P2-2 overlapping the first pad PD1.

In addition, the signal line SL may further include another portion disposed in the first area NBA1 and connected to the first line portion P1. For example, the data line DL shown in FIG. 3 may further include a line portion connected to the first line portion P1, disposed on a layer different from that of the first line portion P1, and overlapping the display area DA.

Referring to FIG. 6B, the first line portion P1 is disposed on the first insulating layer 10. Although the first line portion P1 disposed on the same layer as the gate GT1 of the silicon transistor S-TFT in FIG. 4 is shown as an example, embodiments of the present disclosure are not limited thereto. The first line portion P1 may be disposed on the same layer as the second shielding electrode BMLb in FIG. 4 or the gate GT2 of the oxide transistor O-TFT in FIG. 4. In this regard, “being disposed on the same layer” means being formed by the same process and having the same material and the same stacked structure.

The first line portion P1 may include a stacking of a copper layer and a titanium layer or stacking of a molybdenum layer and the titanium layer stacked from the first insulating layer 10, and the second line portion P2 and the first connection portion CP1 may include the stacking of titanium layer, an aluminum layer, and the titanium layer stacked from the fifth insulating layer 50 or the sixth insulating layer 60.

The first portion CPA1 of the first connection portion CP1 may be connected to the first line portion P1 via at least one first contact hole (e.g., at least one first opening or contact opening) CNT1 defined in the insulating layer disposed between the first portion CPA1 of the first connection portion CP1 and the first line portion P1. FIGS. 6A and 6B show embodiments in which the first portion CPA1 of the first connection portion CP1 and the first line portion P1 are connected to each other via the plurality of first contact holes CNT1. Each of the plurality of first contact holes CNT1 may extend through the second insulating layer 20 to the fifth insulating layer 50, which are the inorganic layers.

It is shown in FIG. 6B that a depth of the first contact holes CNT1 is significantly larger than a diameter thereof; however, embodiments of the present disclosure are not limited thereto. For example, the diameter of the first contact holes CNT1 may be equal to or larger than the depth of the first contact holes CNT1. Further, when the diameter of the first contact holes CNT1 is smaller than the depth of the first contact holes CNT1, a difference therebetween may be small. Because thicknesses of the second insulating layer 20 to the fifth insulating layer 50, which are the inorganic layers, are small, even when the plurality of first contact holes CNT1 are defined in a small area, the difference between the diameter of the first contact holes CNT1 and the depth of the first contact holes CNT1 may be relatively small compared to a difference between a diameter and a depth of contact holes of the same diameter defined in the organic layers, which are described below. Each of the second insulating layer 20 to the fifth insulating layer 50 may have a thickness in a range from 1500 Å to 2500 Å.

The second line portion P2 may be connected to the second portion CPA2 of the first connection portion CP1 via a second contact hole (e.g., a second opening or contact opening) CNT2 defined in the sixth insulating layer 60 disposed between the second line portion P2 and the second portion CPA2 of the first connection portion CP1. In some embodiments, the second contact hole CNT2 extends through the sixth insulating layer 60, which is the organic layer. Among the organic layers 60, 70, 80, and PDL, the organic layer 60 in which the second contact hole CNT2 is formed may be defined as a reference organic layer, and the organic layers 70, 80, and PDL disposed on the reference organic layer may be defined as upper organic layers.

In FIG. 6B, a single second contact hole CNT2 is shown as an example. As the number of contact holes defined in a narrow area decreases, an area occupied by one contact hole may increases. As a diameter of the contact hole increases with respect to a depth thereof, the stress resistance of the structure of the electrode disposed in the contact hole and the insulating layer disposed on the electrode may increase.

The organic layer may have a greater thickness than the inorganic layer. In some examples, the organic layer has a thickness in a range from about 12000 Å to 18000 Å. Further, the second contact hole CNT2 may have a diameter equal to or greater than about 10 micrometers. When the second contact hole CNT2 has the diameter equal to or greater than about 14 micrometers, the first connected portion P2-1 and the seventh insulating layer 70 disposed in the first connected portion P2-1 may further increase in a resistance against the stress. In this regard, the stress occurs when the third area BA is bent, as shown in FIG. 1B.

The second portion CPA2 of the first connection portion CP1 may provide a flat contact area. The first connected portion P2-1 of the second line portion P2 may be in contact with the second portion CPA2 of the first connection portion CP1 across a larger area than that of the first contact holes CNT1. A contact area of the second contact hole CNT2 may be greater than a sum of contact areas of the first contact holes CNT1.

The seventh insulating layer 70, which is one of the upper organic layers 70, 80, and PDL, may be disposed on the sixth insulating layer 60 to cover the second line portion P2. A portion of the seventh insulating layer 70 may be inserted into the second contact hole CNT2. The portion of the seventh insulating layer 70 inserted into the second contact hole CNT2 may be in close contact with the relatively flat first connected portion P2-1 of the second line portion P2.

Referring still to FIG. 6B, because the first insulating layer 210 and the second insulating layer 230 of the input sensor ISL, which are the inorganic layers, overlap the first area NBA1 and do not overlap the third area BA, moisture may have a path of penetration. FIG. 6B shows a first penetration path PR1 of H₂O, according to some examples.

When the first insulating layer 210, which is the inorganic layer, is damaged by outgas generated from the organic layers 60, 70, 80, and PDL disposed below the first insulating layer 210 and the second insulating layer 230 and damaged from the moisture penetrating an interface between the first insulating layer 210 and the pixel defining film PDL, hydrogen radicals and NH₃ gas may be generated from the first insulating layer 210. For example, when the first insulating layer 210, which is the silicon nitride layer, is oxidized, the hydrogen radicals and the NH₃ gas may be generated. The hydrogen radicals and the NH₃ gas react with the penetrating H₂O to generate hydrogen ions and ammonium ions. The hydrogen ions and the ammonium ions diffuse to the first connected portion P2-1 having a negative polarity. The hydrogen ions may reduce (e.g., corrode) the first connected portion P2-1. For example, the hydrogen ions may reduce (e.g., corrode) the aluminum layer and the titanium layer of the first connected portion P2-1. In the reduction reaction, H₂ gas and H₂O are generated, and the H₂ gas and H₂O may weaken a bonding force of the first connected portion P2-1 with the seventh insulating layer 70. For example, the hydrogen ions may react with the aluminum layer to generate the H₂ gas, and the hydrogen ions may react with the titanium oxide of the titanium layer to generate H₂O. In one example, the ammonium ions react with free electrons to generate the NH₃ gas and the H₂ gas. The NH₃ gas and the H₂ gas may again damage the first insulating layer 210 and accelerate the oxidation-reduction reaction described above.

Such oxidation-reduction reaction may occur more readily in the first signal transfer line CLS1 and the second signal transfer line CLS2. When the first signal line receiving the high bias voltage and the second signal line receiving the low bias voltage are disposed adjacent to each other, a potential difference therebetween may attract the hydrogen ions and the ammonium ions. Accordingly, corrosion may occur more easily on the first signal transfer line CLS1 and the second signal transfer line CLS2.

Such corrosion may occur more easily when the insulating layer for covering the signal line is peeled off.

H₂O generated by the reaction of the hydrogen ions with the titanium oxide may be absorbed by the seventh insulating layer 70, which is the organic layer, and the seventh insulating layer 70 may expand as a result. As shown in FIG. 1B, in the state in which the third area BA is bent, the expanded seventh insulating layer 70 may increase compressive stress applied to the signal line SL, particularly, near the second contact hole CNT2. The compressive stress may cause peeling of the seventh insulating layer 70.

However, according to the present embodiment, even when the compressive stress increases, because the portion of the seventh insulating layer 70 is in close contact with the first connected portion P2-1 of the second line portion P2 while being inserted into the second contact hole CNT2 as described above, a defect in which the seventh insulating layer 70 is peeled from the first connected portion P2-1 (or an interface between the seventh insulating layer 70 and the first connected portion P2-1 is lifted) may be prevented or the occurrence of such a defect may be substantially reduced. Because the compressive stress is distributed over a large area, a crack defect of the first connected portion P2-1 of the second line portion P2 may be suppressed, and accordingly, the lifting phenomenon between the first connected portion P2-1 of the second line portion P2 and the seventh insulating layer 70 may be prevented or the occurrence of such a peeling may be substantially reduced.

Referring to FIG. 6C, the organic layers 60, 70, 80, and PDL overlap the second area NBA2 and the third area BA. The seventh and eighth insulating layers 70 and 80 and the pixel defining film PDL might not overlap the second area NBA2. The first insulating layer 210 and the second insulating layer 230 of the input sensor ISL, which are the inorganic layers, overlap the second area NBA2. The first insulating layer 210 and the second insulating layer 230 of the input sensor ISL may cover edges of the seventh and eighth insulating layers 70 and 80 and the pixel defining film PDL.

Referring to FIG. 6C, the third line portion P3 is disposed on the first insulating layer 10. In one embodiment of the present disclosure, the third line portion P3 may be disposed on the same layer as the second shielding electrode BMLb in FIG. 4 or the gate GT2 of the oxide transistor O-TFT in FIG. 4.

The first portion CPA10 of the second connection portion CP2 may be connected to the third line portion P3 via a plurality of third contact holes (e.g., a plurality of third openings or contact openings) CNT3 defined in the second insulating layer 20 to the fifth insulating layer 50. The second line portion P2 may be connected to the second portion CPA20 of the second connection portion CP2 via a single fourth contact hole (e.g., a single fourth opening or contact opening) CNT4 defined in the sixth insulating layer 60. Even when the plurality of fourth contact holes CNT4 are formed, a diameter thereof may be equal to or greater than 10 micrometers, for example.

A second penetration path PR2 similar to the first penetration path PR1 described with reference to FIG. 6B is shown in FIG. 6C. For the same reason as described with reference to FIG. 6B, even when the compressive stress increases, because a portion of the seventh insulating layer 70 is in close contact with the second connected portion P2-2 of the second line portion P2 while being inserted into the fourth contact hole CNT4 as described above, a defect in which the seventh insulating layer 70 is peeled from the second connected portion P2-2 may be prevented or the occurrence of such a defect may be substantially reduced. In addition, because the single fourth contact hole CNT4 distributes the compressive stress over a large area, a crack defect of the second connected portion P2-2 of the second line portion P2 is suppressed, and accordingly, a lifting phenomenon between the second connected portion P2-2 of the second line portion P2 and the seventh insulating layer 70 may be prevented or the occurrence of such a peeling may be substantially reduced.

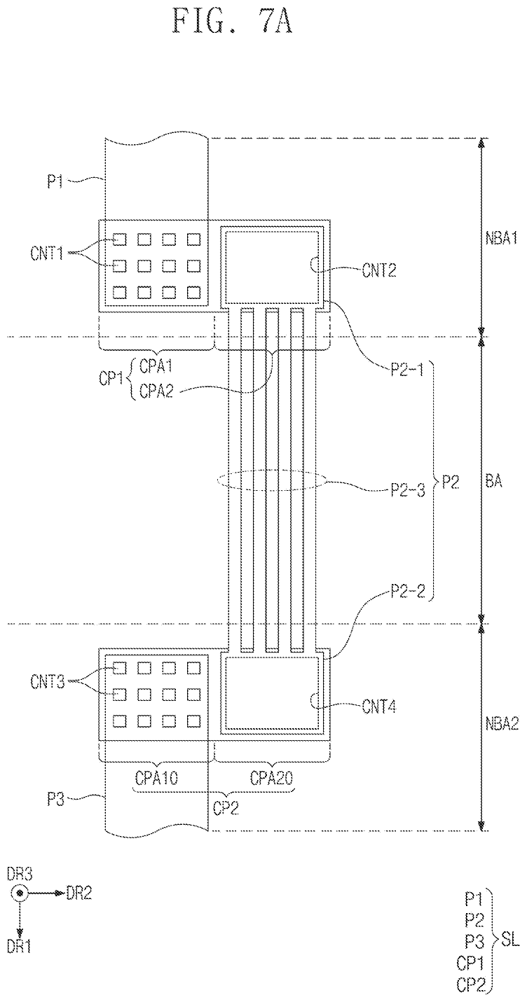

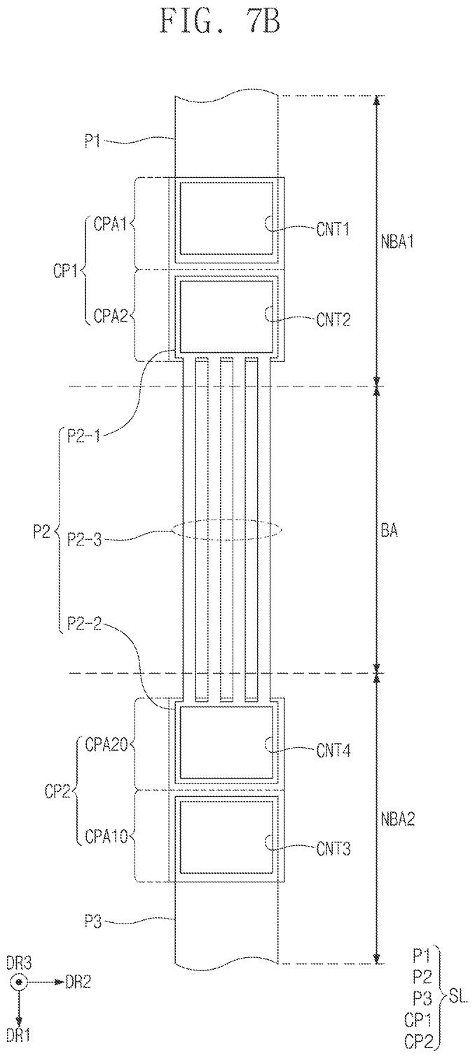

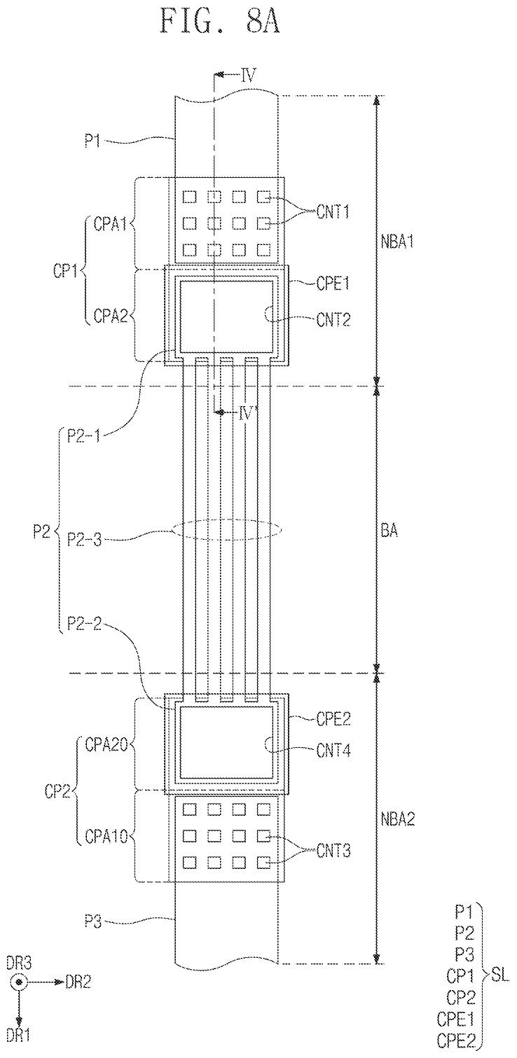

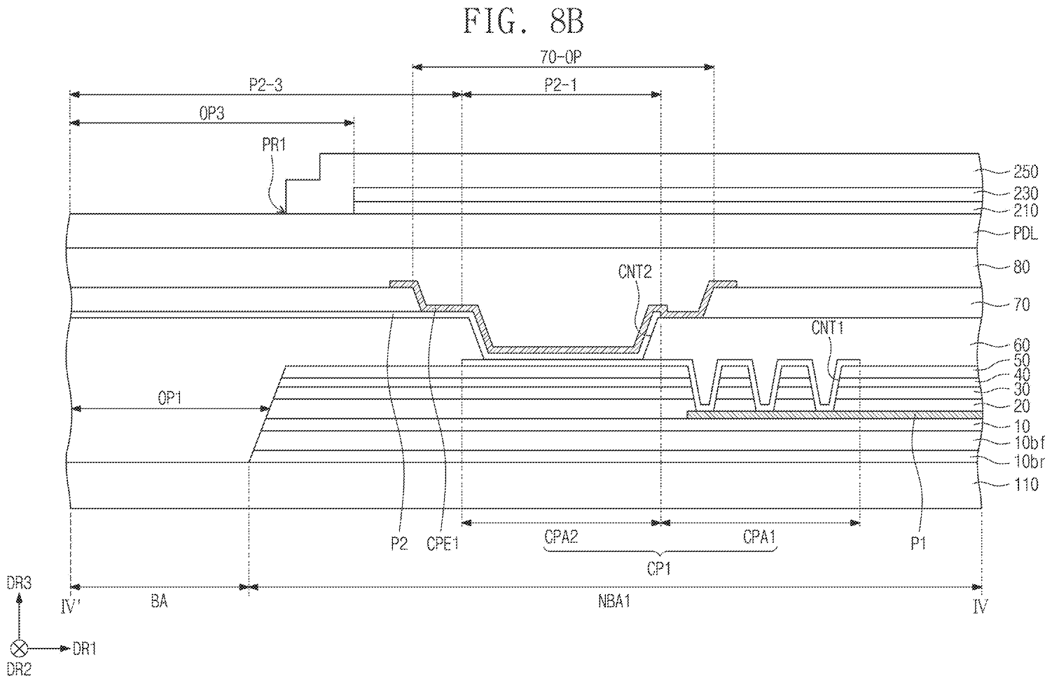

FIGS. 7A and 7B are plan views of the signal line SL according to some embodiments of the present disclosure. FIG. 8A is a plan view of the signal line SL according to some embodiments of the present disclosure. FIG. 8B is a first cross-sectional view of a signal line according to some embodiments of the present disclosure. Hereinafter, a detailed description of the same components as those described with reference to FIGS. 6A to 6C may not be repeated.

Referring to FIG. 7A, the first connection portion CP1 and the second connection portion CP2 extend in the second direction DR2. Lengths in the first direction DR1 of the first area NBA1 and the second area NBA2 arranged around the third area BA may be reduced differently from that shown in FIG. 6A.

Referring to FIG. 7A, it is shown that the first line portion P1 and the third line portion P3 are aligned in the first direction, but the present disclosure is not limited thereto. The third line portion P3 may be disposed on a right side of the second line portion P2.

Referring to FIG. 7B, it may be seen that the plurality of first contact holes CNT1 shown in FIGS. 6A and 7A are replaced with the single first contact hole CNT1, and the plurality of third contact holes shown in FIGS. 6A and 7A are replaced with the single third contact hole CNT3. Because contact areas of the single first contact hole CNT1 and the single third contact hole CNT3 are increased, a coupling force with the sixth insulating layer 60 (see, e.g., FIGS. 6B and 6C) disposed above may be increased.

Referring to FIG. 8A, the signal line SL may further include a first capping electrode CPE1 and a second capping electrode CPE2. The first capping electrode CPE1 is disposed to correspond to the second contact hole CNT2, and the second capping electrode CPE2 is disposed to correspond to the fourth contact hole CNT4. Hereinafter, because the second capping electrode CPE2 has the same structure and the same function as those of the first capping electrode CPE1, the following description may primarily focus on the first capping electrode CPE1.

Referring to FIG. 8B, the first capping electrode CPE1 may be formed via the same process as the third connecting electrode CNE3 shown in FIG. 4. An opening 70-OP may be defined in the seventh insulating layer 70 to overlap the second contact hole CNT2. The second contact hole CNT2 is defined inwardly from the opening 70-OP on the plane.

The opening 70-OP of the seventh insulating layer 70 may expose the first connected portion P2-1. At least a portion of the first capping electrode CPE1 is disposed in the opening 70-OP of the seventh insulating layer 70 to cover the first connected portion P2-1. A portion of the eighth insulating layer 80 is disposed in the opening 70-OP of the seventh insulating layer 70 to cover the first capping electrode CPE1.

In one embodiment of the present disclosure, the seventh insulating layer 70 might not be disposed in the third area BA, and the opening 70-OP of the seventh insulating layer 70 may extend up to the third area BA.

When a bonding force between the eighth insulating layer 80 and the first capping electrode CPE1 is greater than the bonding force between the seventh insulating layer 70 and the first connected portion P2-1, as described with reference to FIG. 6B, even when the compressive stress increases, peeling between the eighth insulating layer 80 and the first capping electrode CPE1 may occur less than the peeling between the seventh insulating layer 70 and the first connected portion P2-1. When forming conditions of the seventh insulating layer 70 are less favorable than forming conditions of the eighth insulating layer 80 and accordingly an insulating layer with weak bonding force is formed, the opening 70-OP may be defined as shown in FIG. 8B. In addition, the opening 70-OP extending from the second contact hole CNT2 and the first capping electrode CPE1 disposed with a larger area than the first connected portion P2-1 may distribute the stress occurred when the third area BA (see, e.g., FIG. 1B) is bent.

As described above, the area of the bezel area of the display device may be reduced by bending the non-display area.

The peeling of the organic film from the signal line may be reduced by increasing the contact area between the signal line and the organic film around the bezel area. A damage to the portion disposed inside the contact hole caused by the compressive stress, tensile stress, or shear stress may be reduced by lowering a step of the contact hole for connecting different portions of the signal line to each other.

The corrosion of the first line portion and the first portion of the first connection portion may be suppressed by separating the first line portion and the first portion of the first connection portion away from the penetration path of the moisture.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present. Further, the phrase “directly disposed” may mean that there is no layer, film, region, plate or the like between a portion of a layer, film, region, plate or the like and another portion. For example, “directly disposed” may mean that one or more adhesive members are not disposed between two layers or two members.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

While the present disclosure has been described with reference to some example embodiments thereof, it will be apparent to those of ordinary skill in the art that various suitable changes and modifications may be made thereto without departing from the spirit and scope of the present disclosure as defined by the following claims, and equivalents thereof.

What is claimed is:

1. A display device comprising:
a base substrate comprising a first area, a second area spaced apart from the first area in a first direction, and a third area between the first area and the second area in the first direction and bendable to a set degree;
a plurality of insulating layers on the base substrate;
a pixel on the first area; and
a signal line overlapping the first area, the second area, and the third area,
wherein the signal line comprises:
a first line portion in the first area;
a second line portion in the first area, the second area, and the third area and on a layer different from a layer of the first line portion; and
a first connection portion in the first area and on a layer different from layers of the first line portion and the second line portion,
wherein a first portion of the first connection portion is connected to the first line portion via at least one first contact hole defined in a first insulating layer of the insulating layers between the first portion of the first connection portion and the first line portion, and
wherein the second line portion is connected to a second portion of the first connection portion via a single second contact hole defined in a second insulating layer of the insulating layers between the second line portion and the second portion of the first connection portion, the second insulating layer being an organic layer.

2. The display device of claim 1, wherein the signal line further comprises:
a third line portion in the second area; and
a second connection portion in the second area and on a layer different from layers of the second line portion and the third line portion,
wherein a first portion of the second connection portion is connected to the third line portion via at least one third contact hole defined in a third insulating layer of the insulating layers between the first portion of the second connection portion and the third line portion, and
wherein the second line portion is connected to a second portion of the second connection portion via a single fourth contact hole defined in a fourth insulating layer of the insulating layers between the second line portion and the second portion of the second connection portion, the fourth insulating layer being an organic layer.

3. The display device of claim 2, wherein the second insulating layer and the fourth insulating layer are a same organic layer.

4. The display device of claim 1, wherein the at least one first contact hole comprises a plurality of first contact holes,
wherein the first insulating layer comprises a plurality of inorganic layers.

5. The display device of claim 4, wherein the organic layer is on the plurality of inorganic layers.

6. The display device of claim 4, wherein a contact area of the second contact hole is larger than a sum of contact areas of the plurality of first contact holes.

7. The display device of claim 1, wherein a diameter of the second contact hole is equal to or greater than 10 micrometers.

8. The display device of claim 1, wherein the second line portion comprises:
a connected portion overlapping the second portion of the first connection portion; and
a plurality of line portions extending in the first direction from the connected portion, arranged in a second direction crossing the first direction, and overlapping the third area.

9. The display device of claim 1, further comprising:
a scan driving circuit that is in the first area and provides a scan signal to the pixel,
wherein the signal line is connected to the scan driving circuit.

10. The display device of claim 9, wherein the signal line comprises a first signal line configured to receive a first bias voltage and a second signal line configured to receive a second bias voltage lower than the first bias voltage.

11. The display device of claim 10, wherein a voltage difference between the first bias voltage and the second bias voltage is equal to or greater than about 10 V.

12. The display device of claim 1, wherein the signal line is electrically connected to the pixel.

13. The display device of claim 1, wherein the plurality of insulating layers comprises:
a plurality of upper organic layers overlapping the first area and on the first line portion and the first connection portion; and
at least one inorganic layer overlapping the first area, not overlapping the third area, and on the plurality of upper organic layers.

14. The display device of claim 13, wherein a portion of an upper organic layer in contact with the first line portion among the plurality of upper organic layers is inside the second contact hole.

15. The display device of claim 1, further comprising:
a capping electrode,
wherein the plurality of insulating layers overlaps the first area and the third area, and comprise a first organic layer on the second line portion and a second organic layer on the first organic layer,
wherein the first organic layer defines an opening overlapping the second contact hole and exposing a portion of the second line portion, and
wherein the capping electrode is on the exposed portion of the second line portion.

16. The display device of claim 15, wherein the second contact hole is inside the opening in a plan view.

17. The display device of claim 1, wherein the first area of the first connection portion and the second area of the first connection portion are aligned in a second direction crossing the first direction.

18. A display device comprising:
a base substrate comprising a first area, a second area spaced apart from the first area in a first direction, and a third area between the first area and the second area;
a plurality of inorganic layers on the base substrate, and defining an opening extending in a second direction crossing the first direction and overlapping the third area;
a plurality of organic layers on the plurality of inorganic layers;
a pixel on the base substrate and overlapping the first area; and
a signal line overlapping the first area, the second area, and the third area,
wherein the signal line comprises:
a first line portion in the first area;
a second line portion in the first area, the second area, and the third area and on a layer different from a layer of the first line portion; and
a first connection portion in the first area and on a layer different from layers of the first line portion and the second line portion,
wherein a first portion of the first connection portion is connected to the first line portion via a plurality of first contact holes defined in at least one inorganic layer of the inorganic layers between the first portion of the first connection portion and the first line portion,
wherein the second line portion is connected to a second portion of the first connection portion via a second contact hole defined in at least one organic layer of the organic layers between the second line portion and the second portion of the first connection portion, and
wherein a diameter of the second contact hole is equal to or greater than about micrometers.

19. The display device of claim 18, wherein a portion of an organic layer on the at least one organic layer among the plurality of organic layers is inside the second contact hole.

20. The display device of claim 18, further comprising:
a capping electrode,
wherein an opening having a larger area than the second contact hole and exposing a portion of the second line portion is defined in a first upper organic layer on the at least one organic layer among the plurality of organic layers,
wherein the capping electrode is inside the opening and covers the exposed portion of the second line portion, and
wherein a second upper organic layer on the first upper organic layer is inside the opening.
